(19) United States
(12) Patent Application Publication
(10) Pub. No.: US 2008/0017947 A1
(43) Pub. Date: Jan. 24, 2008

(54) CIRCUIT HAVING A SCHOTTKY CONTACT COMPONENT

(75) Inventor: Michael Treu, Villach (AT)

Correspondence Address: DICKE, BILLIG & CZAJA, FIFTH STREET TOWERS, 100 SOUTH FIFTH STREET, SUITE 2250, MINNEAPOLIS, MN, 55402, US

(73) Assignee: INFINEON TECHNOLOGIES AG, Neubiberg (DE)

(21) Appl. No.: 11/780,265

(22) Filed: Jul. 19, 2007

(30) Foreign Application Priority Data
Jul. 19, 2006 (DE) 10 2006 033 506.6

(51) Int. Cl. H01L 27/095; H01L 29/00

(52) U.S. Cl. 257/476; 257/471; 257/522; 257/E29.002; 257/E27.001

(57) ABSTRACT

A circuit having a Schottky contact component is disclosed. One embodiment provides a semiconductor substrate having a layer of a first conductivity type, a metal layer, and delimited semiconductor regions of a second conductivity type opposite the first conductivity type, provided in or on the main surface, in order to increase the resistance of the Schottky contact component to overcurrents. At least the predominant number of delimited semiconductor regions of the second conductivity type being provided in the form of islands with a predetermined distance greater than a minimum interaction distance required for interaction of the islands to achieve an associated shielding effect.

### CROSS-REFERENCE TO RELATED APPLICATIONS

This Utility Patent Application claims priority to German Patent Application No. DE 10 2006 033 506.6 filed on Jul. 19, 2006, which is incorporated herein by reference.

### BACKGROUND

The invention relates to a circuit having a Schottky contact component, for instance a Schottky diode, having an adjustable resistance to overcurrents and a low reverse current.

Schottky diodes have been used for a long time as extremely fast switching diodes, as diodes for clocked switched-mode power supplies. In addition, the use of Schottky barriers in fast circuits, such as polar circuits (so-called “Schottky TTL”), has been known for a long time, to be precise in order to avoid the hole storage effect there.

Schottky diodes have been increasingly used for some time for applications with relatively high voltages but their production is simultaneously subject to the trend of implementing semiconductor components with increasingly thin substrates. Another important trend is to increasingly produce Schottky diodes on SiC substrates rather than on Si substrates. This necessitates design considerations which take account of the particular electronic properties of this substrate material.

For general cost considerations, it is also appropriate, in the case of Schottky contact components of the type in question, to produce the latter using as little semiconductor substrate area (“chip area”) as possible with predetermined performance parameters.

Schottky diodes on thin SiC substrates are marketed by the applicant under the name “thinQ!2G”. These silicon carbide Schottky diodes are optimized for active power factor correction (PFC) in switched-mode power supplies and have far higher resistance to current surges and improved robustness in comparison with previous types and are also designed for higher switch-on currents and transient current pulses. On account of the fact that system developers and power supply unit manufacturers can dispense with overdimensioning when using these novel Schottky diodes, smaller and less expensive diodes can be used in conjunction with simultaneously increased reliability, which entails a considerable potential saving during system development.

A merged pn Schottky construction is used in the current generation of thinQ!2G SiC Schottky diodes. Two aspects are combined in this construction: firstly, a pn diode characteristic can be achieved in the event of overloading as a result of the pn junctions which have been incorporated and, secondly, the p-type regions shield the Schottky regions from the electrical field in the space charge zone and can thus reduce the reverse current at the Schottky contact.

One disadvantage of this construction is that the p⁺-type regions take up a relatively large amount of area and only less than 50% of the contact area is still available for the Schottky contact, thus increasing the voltage drop in the forward direction. Although the resistance of the epitaxial layer can be selected to be lower than in the case of a pure Schottky diode on account of the fact that the Schottky regions are shielded by the p-type regions, the loss of area for the Schottky contact cannot be completely compensated for and the merged pn Schottky diode becomes 20%-25% larger than a pure Schottky diode.

During further development, it is planned to decrease the series resistivity further by using thinner substrates. As a result, the resistance to overloading will also increase and, under certain circumstances, values which cannot be used in the application will be achieved. However, the construction described above does not make it possible to reduce the resistance to overloading in favor of less chip area because the distances between the p-type regions can be selected only in a very small range on account of the shielding required.

For these and other reasons, there is a need for the present invention.

### BRIEF DESCRIPTION OF THE DRAWINGS

The accompanying drawings are included to provide a further understanding of embodiments and are incorporated in and constitute a part of this specification. The drawings illustrate embodiments and together with the description serve to explain principles of embodiments. Other embodiments and many of the intended advantages of embodiments will be readily appreciated as they become better understood by reference to the following detailed description. The elements of the drawings are not necessarily to scale relative to each other. Like reference numerals designate corresponding similar parts.

FIG. 1 illustrates a vertical cross-sectional illustration through an integrated circuit including the component structure of a Schottky contact component.

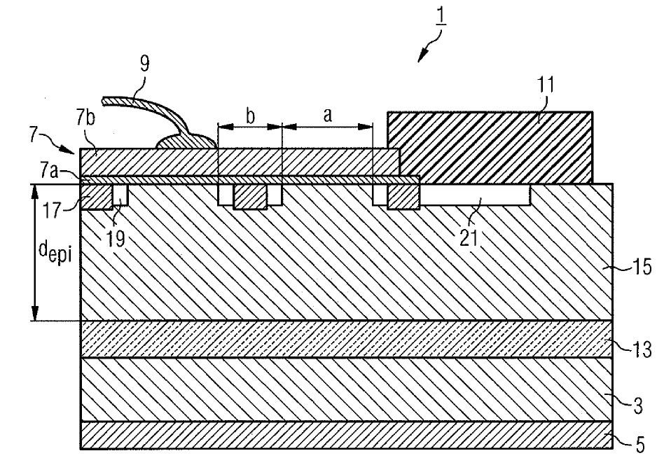

### DETAILED DESCRIPTION

In the following Detailed Description, reference is made to the accompanying drawings, which form a part hereof, and in which is shown by way of illustration specific embodiments in which the invention may be practiced. In this regard, directional terminology, such as “top,” “bottom,” “front,” “back,” “leading,” “trailing,” etc., is used with reference to the orientation of the FIGURE(S) being described. Because components of embodiments can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

It is to be understood that the features of the various exemplary embodiments described herein may be combined with each other, unless specifically noted otherwise.

The invention achieves further improvement of the cost/performance ratio of a Schottky contact component.

One or more embodiments include the fundamental concept of deliberately departing from the previously pursued objective of using semiconductor regions of the second conductivity type in a layer of the first conductivity type on the surface of the component in order to achieve an improved shielding effect. In connection with this, it also includes the concept of considerably reducing the lateral distances between the regions of the second conductivity type or their correlation to one another, that is to say of designing them in the form of islands which are relatively isolated geometrically and electronically, with the result that only their effect is still used to increase the resistance to overcurrents.

This solution achieves the entirely fundamental technological advantage that the size and number of regions of the second conductivity type as well as their spatial arrangement relative to one another can be freely selected within a wide range on the only condition that the corresponding pn junctions are “switched on” effectively in the event of overloading. In particular, this also achieves the effect, which is highly desirable for reasons of cost, that the increase in the area of the overall component caused by their presence is kept within narrow limits and, in particular, in the region of a few percent.

One embodiment provides for the defect concentration of the islands of the second conductivity type to be greater than that of a semiconductor substrate of the first conductivity type. This therefore means that, in the case of a semiconductor substrate of the p type, the islands are of the n⁺ type and, in the case of a semiconductor substrate of the n type, the islands are of the p⁺ type.

In the integrated circuit having a Schottky contact component according to one or more embodiments, provision is also preferably made for the islands of the second conductivity type to be surrounded by edge regions of the second conductivity type with a reduced defect concentration. For example, in the case of islands of the p⁺ type, there are thus surrounding regions of the p⁻ type or, in the case of islands of the n⁺ type, there are surrounding regions of the n⁻ type. With a suitable design of an implantation process for producing the islands, these edge regions which are preferably provided result, if appropriate, to a sufficient extent from scattering effects during implantation irradiation, but a special implantation process for producing them with a defined defect concentration or a defined concentration profile may also be provided. Such an additional process is generally required for the preferred values for the width which are mentioned further below.

The field boosting caused by incorporating relatively highly doped regions of the second conductivity type in the layer of the first conductivity type can be reduced to the greatest possible extent in the edge regions of the incorporated regions as a result of the abovementioned measure.

Within the scope of the abovementioned degrees of design freedom, it is expedient for typical applications if the islands of the second conductivity type have an average distance which is considerably greater than the thickness of the layer of the first conductivity type. Similarly, it is normally expedient if the average lateral dimension of the islands of the second conductivity type is in the range of one to three times the thickness, in one embodiment twice the thickness, of the layer of the first conductivity type. Both parameters are typically related to one another such that the distance between the islands of the second conductivity type is between two and four times their lateral dimension. However, reference is expressly made to the fact that these dimensioning rules are to be understood merely as orientation values and other relationships between these parameters may also be expedient on account of other design specifications.

In the case of the embodiment which was discussed further above and has edge regions of the islands with a reduced defect concentration, it is preferred for the average width of the edge regions to be 300 nm or more. However, other values—down to completely dispensing with the less highly doped edge regions, that is to say a width of zero—are possible in this case too.

Another embodiment provides for the layer of the first conductivity type to be in the form of an epitaxial layer for increasing the breakdown strength above a field stop layer in an SiC substrate. However, in principle, the invention can also be used in a beneficial manner for correspondingly designed Schottky contact components in an Si substrate.

Use of the invention is particularly expedient in particularly thin components, that is to say if, for instance, the thickness of the semiconductor substrate is 100 μm or less.

As regards the question of costs discussed above, the number and lateral dimension of the islands are defined in such a manner that their proportion of the effective area of the Schottky contact component is less than 20%, in one embodiment less than 10% and particularly 5% or less. In principle, the smallest possible additional outlay on area in comparison with an arrangement without pn junctions should be strived for but this design objective is weighed up against reliably achieving the actual objective when providing the regions of the second conductivity type, namely improving the overload behavior of the component.

The FIGURE illustrates a circuit having a Schottky component 1 which is constructed on a thin SiC substrate 3. In one embodiment, the circuit is an integrated circuit.

The rear side of the SiC substrate has a rear side metallization 5, while the front side (first main surface) has a front side metallization 7 which includes a thin Ti layer 7a, for example, and an Al layer 7b above the latter and is connected by using a wire bonding connection 9. Together with the associated main area of the SiC substrate, the front side metallization 7 forms the actual Schottky contact which is enclosed by a polyimide edge layer 11 as an insulation layer.

A field stop layer 13 is provided in the SiC substrate 3, which is of the n type in the embodiment illustrated here, at a predetermined depth under the first main area, and an epitaxially deposited, likewise n-doped SiC layer 15, which is also referred to as an epitaxial layer in view of the manner in which it is produced, is applied to the field stop layer. The thickness of the SiC layer is denoted dₑₚᵢ in the FIGURE.

Embedded in the surface of the epitaxial layer 15 are p⁺-doped islands 17 whose edge is surrounded by p⁻-doped edge regions 19 and which, together with the latter, have a lateral extent which is denoted b in the Figure. The islands 17 (with the edge regions 19) are arranged at a distance a in the epitaxial layer 15. Since the edge region of the actual component 1 should also be p-conducting under the insulation layer 11, a further p-type doping region 21 (which is, in particular, frame-like or annular in plan view) is provided there.

A relatively large distance a between the p⁺-type islands 17, which is considerably larger than the thickness dₑₚᵢ of the epitaxial layer 15, in one embodiment is essential to the function of the Schottky contact component 1. In accordance with the desired component characteristics and the additional amount of area which is used and must be accepted, the lateral extent of the islands 17 with their edge regions 19 can be selected in a relatively free manner in comparison with a “pure” Schottky contact component and can typically be 2 dₑₚᵢ, for instance. In absolute values, the lateral extent b can be, for example, between 2 and 4 μm, of which the extent of the edge regions is typically in the range between 200 and 300 nm.

In this range of lateral extent mentioned here, the p⁻-type edge regions 19 can be produced in the form of edge regions or scattering regions with the corresponding irradiation given a suitable design of the implantation processes for producing the p⁺-type islands 17. In modified embodiments, they may either also be eliminated or may be formed with a precisely predetermined defect concentration and lateral dimension using a separate implantation process.

The scope of the invention is not restricted to the example described here and to the aspects emphasized in this case but is likewise possible in a multiplicity of variations which are within the scope of ordinary skill in the art. In particular, all combinations of the features of the dependent claims are intended to be regarded as being within the scope of the invention.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A circuit having a Schottky contact component comprising:
a semiconductor substrate having a layer of a first conductivity type, a metal layer arranged on the layer, and semiconductor regions of a second conductivity type opposite the first conductivity type, provided in or on the main surface; and
wherein at least a predominant number of the semiconductor regions of the second conductivity type are provided in the form of islands with a predetermined distance greater than a minimum interaction distance required for interaction of the islands and needed to achieve an associated shielding effect.

2. The circuit of claim 1, comprising wherein a defect concentration of the islands of the second conductivity type is greater than that of a semiconductor substrate of the first conductivity type.

3. The circuit of claim 1, comprising wherein the islands of the second conductivity type are surrounded by edge regions of the second conductivity type with a reduced defect concentration.

4. The circuit of claim 1, comprising wherein the islands of the second conductivity type have an average distance which is considerably longer than the thickness of the layer of the first conductivity type.

5. The circuit of claim 1, comprising wherein the average lateral dimension of the islands of the second conductivity type is in the range of one to three times the thickness of the layer of the first conductivity type.

6. The circuit of claim 1, comprising wherein the distance between the islands of the second conductivity type is between two and four times their lateral dimension.

7. The circuit of claim 3, comprising wherein an average width of the edge regions is 300 nm or more.

8. The circuit of claim 1, comprising wherein the layer of the first conductivity type is in the form of an epitaxial layer configured for increasing the breakdown strength, the epitaxial layer being provided above a field stop layer in an SiC substrate.

9. The circuit of claim 1, comprising wherein the first conductivity type is n type and the second conductivity type is p type.

10. The circuit of claim 1, comprising wherein a thickness of the semiconductor substrate is 100 μm or less.

11. The circuit of claim 1, comprising wherein the number and lateral dimension of the islands are defined such that their proportion of an effective area of the Schottky contact component is less than 20%.

12. The circuit of claim 1, where the circuit is an integrated circuit.

13. A circuit of claim 1, wherein the circuit is configured for active power factor correction in a switched-mode power supply.

14. A Schottky contact component comprising:
a semiconductor substrate having a layer of a first conductivity type, a metal layer arranged on the layer, and semiconductor regions of a second conductivity type opposite the first conductivity type, provided in or on the main surface, to increase the resistance of the Schottky contact component to overcurrents; and
wherein at least a predominant number of the semiconductor regions of the second conductivity type are provided in the form of islands with a predetermined distance greater than a minimum interaction distance required for interaction of the islands and needed to achieve an associated shielding effect.

15. The Schottky contact component of claim 14, comprising wherein a defect concentration of the islands of the second conductivity type is greater than that of a semiconductor substrate of the first conductivity type.

16. The Schottky contact component of claim 14, comprising wherein the islands of the second conductivity type are surrounded by edge regions of the second conductivity type with a reduced defect concentration.

17. The Schottky contact component of claim 14, comprising wherein the islands of the second conductivity type have an average distance considerably longer than the thickness of the layer of the first conductivity type.

18. The Schottky contact component of claim 14, comprising wherein an average lateral dimension of the islands of the second conductivity type is in the range of twice the thickness of the layer of the first conductivity type.

19. The Schottky contact component of claim 14, comprising wherein the distance between the islands of the second conductivity type is between two and four times their lateral dimension.

20. The Schottky contact component of claim 16, comprising wherein an average width of the edge regions is 300 nm or more.

21. The Schottky contact component of claim 14, comprising wherein a layer of the first conductivity type is in the form of an epitaxial layer for increasing the breakdown strength, the epitaxial layer being provided above a field stop layer in an SiC substrate.

22. The Schottky contact component of claim 14, comprising wherein the first conductivity type is n type and the second conductivity type is p type.

23. The Schottky contact component of claim 14, comprising wherein a thickness of the semiconductor substrate is 100 μm or less.

24. The Schottky contact component of claim 14, comprising wherein the number and lateral dimension of the islands are defined in such a manner that their proportion of the effective area of the Schottky contact component is less than 20%, preferably less than 10% and particularly preferably 5% or less.

25. A circuit having a Schottky contact component comprising:
a semiconductor; and
means for increasing the resistance of the Schottky contact component to overcurrents, including a semiconductor substrate having a layer of a first conductivity type, a metal layer arranged on the layer, and semiconductor regions of a second conductivity type opposite the first conductivity type, provided in or on the main surface; and
wherein at least a predominant number of the semiconductor regions of the second conductivity type are provided in the form of islands with a predetermined distance greater than a minimum interaction distance required for interaction of the islands and needed to achieve an associated shielding effect.
